(19) United States
(12) Patent Application Publication
(10) Pub. No.: US 2025/0324692 A1
(43) Pub. Date: Oct. 16, 2025

(54) SCALED STACKED FET USING COMBINED STRUCTURES IN ADJACENT CELLS

(71) Applicant: INTERNATIONAL BUSINESS MACHINES CORPORATION, Armonk, NY (US)

(72) Inventors: Debarghya Sarkar, Latham, NY (US); Ruilong Xie, Niskayuna, NY (US); Shay Reboh, Guilderland, NY (US); Abir Shadman, Albany, NY (US); Junli Wang, Slingerlands, NY (US)

(21) Appl. No.: 18/632,599

(22) Filed: Apr. 11, 2024

(51) Int. Cl. H01L 29/08; H01L 23/522; H01L 23/528; H01L 27/06; H01L 27/088; H01L 29/417

(52) U.S. Cl. CPC H10D 62/151; H01L 23/5226; H01L 23/5283; H10D 64/251; H10D 84/83; H10D 88/00

(57) ABSTRACT

A semiconductor device includes a first cell adjacent to a second cell, the first cell including first stacked source/drain regions on two levels. The second cell includes second stacked source/drain regions on the at least two levels. The first cell has a first tapered vertical conductor and the second cell has a second tapered conductor with a taper opposite that of the first tapered vertical conductor to reduce cell heights of the first cell and the second cell.

### BACKGROUND

The present invention generally relates to semiconductor devices and processing methods, and more particularly to stacked field effect transistors (FETs) with structure shapes in adjacent cells employed to scale the stacked FETs to achieve overall reduced cell height.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

Area scaling of stacked FETs is limited by lateral space requirements of contact connections. Reducing cell height to two pitches of M1 metal lines is a challenge as it leads to very narrow tip-to-tip contact dimensions that will cause shorts between contacts. A reliable structure is needed to reduce the cell height for stacked FET while keeping a same sheet width and contact dimensions and avoiding narrow tip-to-tip contact dimensions.

### SUMMARY

In accordance with an embodiment of the present invention, a semiconductor device includes a first cell adjacent to a second cell, the first cell including first stacked source/drain regions on two levels. The second cell includes second stacked source/drain regions on the at least two levels. The first cell has a first tapered vertical conductor and the second cell has a second tapered conductor with a taper opposite that of the first tapered vertical conductor to reduce cell heights of the first cell and the second cell.

In accordance with another embodiment of the present invention, a semiconductor device includes a first cell adjacent to a second cell. The first cell has a first tapered vertical conductor that traverses two stacked source/drain regions in the first cell. The second cell has a second tapered vertical conductor that traverses a first stacked source/drain region in the second vertical cell and connects to a second stacked source/drain region in the second cell. The second tapered vertical conductor is adjacent to the first tapered vertical conductor. The second tapered vertical conductor includes a taper opposite that of the first tapered vertical conductor to reduce cell heights of the first cell and the second cell.

In accordance with another embodiment of the present invention, a semiconductor device includes a first cell including first stacked source/drain regions having a substantially same width on at least two levels. An extended backside via extends from a backside of the semiconductor device to a frontside of the semiconductor device. A second cell is adjacent to the first cell and includes second stacked source/drain regions on the at least two levels with different widths. A second tapered vertical conductor in the second cell has a taper opposite that of the extended backside via to reduce cell heights of the first cell and the second cell which are each within two pitches of M1 metal lines. A backside contact is connected to one of the first stacked source/drain regions and the extended backside via at a backside of the semiconductor device.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view, taken at section line Y1 as shown in an inset (and referred to as section Y1), of a semiconductor device having stacked field effect transistors, in accordance with an embodiment of the present invention;

FIG. 2 shows a cross-sectional view, taken at section line Y1, depicting a contact formed that connects to a wider bottom source/drain region from a frontside, in accordance with an embodiment of the present invention;

FIG. 3 shows a cross-sectional view, taken at section line Y1, depicting an offset contact formed that connects to a top source/drain region from a frontside, in accordance with an embodiment of the present invention;

FIG. 4 shows a cross-sectional view, taken at section line Y1, depicting contacts formed that connect to top source/drain regions from a frontside, in accordance with an embodiment of the present invention;

FIG. 5 shows a cross-sectional view, taken at section line Y1, depicting top level metallization formed that connects to the contacts for the top source/drain regions and the offset contact from a frontside, in accordance with an embodiment of the present invention;

FIG. 6 shows a cross-sectional view, taken at section line Y1, depicting a carrier wafer added to a back end of line layer, a substrate removed and replaced by a backside interlayer dielectric layer and an extended backside via formed that connects to vias formed on a frontside, in accordance with an embodiment of the present invention;

FIG. 7 shows a cross-sectional view, taken at section line Y1, depicting the extended backside via recessed and nested with the offset contact, in accordance with an embodiment of the present invention;

FIG. 8 shows a cross-sectional view, taken at section line Y1, depicting a backside contact opening to expose the extended backside via and a sacrificial placeholder, in accordance with an embodiment of the present invention;

FIG. 9 shows a cross-sectional view, taken at section line Y1, depicting the sacrificial placeholder removed, in accordance with an embodiment of the present invention;

FIG. 10 shows a cross-sectional view, taken at section line Y1, depicting a backside contact formed, in accordance with an embodiment of the present invention;

FIG. 11 shows a cross-sectional view, taken at section line Y1, depicting a thicker dielectric liner for shallow trench isolation regions, in accordance with an embodiment of the present invention;

FIG. 12 shows a cross-sectional view, taken at section line Y1, depicting a carrier wafer added to a back end of line layer, a substrate removed and replaced by a backside interlayer dielectric layer and an extended backside via opening formed through a shallow trench isolation region to form a dielectric collar, in accordance with an embodiment of the present invention; and

FIG. 13 shows a cross-sectional view, taken at section line Y1, depicting the extended backside via opening extended to expose vias, in accordance with an embodiment of the present invention.

### DETAILED DESCRIPTION

In accordance with embodiments of the present invention, devices and methods are described which include controlling a size and shape of structures in adjacent cells to permit scaling of cell height. In an embodiment, complementary stacked field effect transistor designs are employed in adjacent cells that permit reduced cell height and prevent shorting between adjacent via chains. In an example, a first cell can include an I-shape and an adjacent cell can include an L-shape to maintain sufficient dielectric material between via chains in the adjacent cells while permitting the two cells to fit within a two M1 pitch width.

The I-shaped cell includes epi-regions that are substantially a same size or are closer in size between a top epi region and a bottom epi region. A backside contact connects a bottom epi region with an extended backside via. The extended backside via is formed from a backside of a wafer. The L-shaped cell is adjacent to the I-shaped cell and includes epi-regions that are different in size between a top epi region and a bottom epi region. The bottom epi region is large providing the L-shape. An offset contact is formed adjacent to the extended backside via and complements the extended backside via making an efficient use of available space. Using middle of the line (MOL) flipped orientations between vertical conductors (e.g., contacts or vias) in adjacent cells, a smallest gap between the two vertical conductors is increased, preventing shorting between the vertical conductors of adjacent devices. This also permits for scaling cell height of a stacked field effect transistor (FET) to less than two M1 pitches while keeping a large sheet width and providing adequate space for interconnects.

In useful embodiments, a semiconductor device includes a stacked field effect transistor (FET) with adjacent cells having complementary profiles, e.g., I-shape and L-shape. A bottom FET signal line for the I-shaped cell is connected by a backside contact, while a bottom FET signal line of the L-shaped cell is connected by a frontside contact. The backside and frontside contacts have inverted orientations relative to each other, e.g., a positive taper versus a negative taper (or vice versa). This permits a cell height equal to or less than two M1 pitches.

In other embodiments, methods to form a semiconductor device include forming a stacked FET with top and bottom S/D epi regions and replacement metal gates (RMG), where an I-shaped device is in a first cell, and an L-shaped device is in a second cell adjacent to the first cell. A frontside contact or via is formed to a bottom epi region of the L-shaped device from a frontside. Top epi region contacts are formed, and frontside interconnects are formed. A carrier wafer is bonded to the wafer and the wafer is flipped. A substrate is removed and a backside interlayer dielectric layer (BILD) is deposited. A backside contact and via are formed to a bottom epi region of the I-shaped device and frontside contacts from a backside. Backside interconnects are formed.

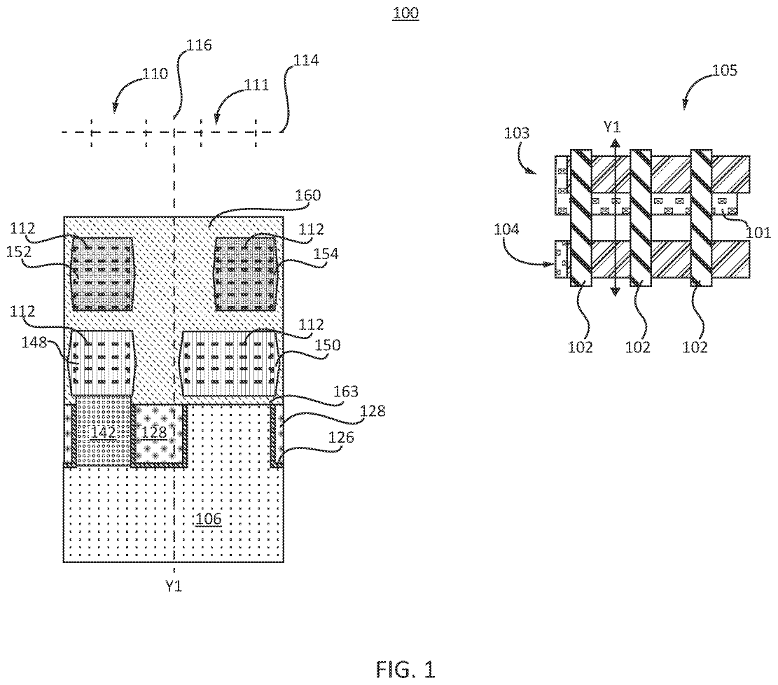

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 106 having one or more layers on which the stacked FET device will be fabricated. FIG. 1 depicts a cross-sectional view Y1 taken at corresponding section Y1 in inset 105. Inset 105 shows gate lines 102 and active region lines 103 and 104. Corresponding Y1 views are depicted throughout the FIGS. Active region lines 103 represent source/drain (S/D) regions for transistor devices to be formed having an L-shaped arrangement. Active region lines 104 represent S/D regions for transistor devices to be formed having an I-shaped arrangement. Active region lines 103 include a wider bottom S/D region 101. Transistor channels are formed on the active region lines 103, 104 below the gate lines 102.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A stack or stacks are applied to or formed on the substrate 106. In one embodiment, one or more nanosheets (NS) are applied to the substrate 106. In another embodiment, the stacks can be epitaxially grown using different chemistries to form layers having different properties. In an embodiment, a stack includes semiconductor layers 112 that form transistor channels. The semiconductor layers 112 that form transistor channels are depicted in dashed lines as they are positioned behind source/drain regions in the cross-section depicted. In an embodiment, semiconductor layers 112 include Si. It should be understood that other materials can be employed for semiconductor layers 112. In other embodiments, different stacks and configurations may be employed for semiconductor layers 112.

Substrate 106 is patterned and etched to form shallow trenches therein. Shallow trench isolation (STI 128) or STI region is formed in the etched trenches. STI 128 can be formed by depositing dielectric material, such as, e.g., SiO₂, SiOₓN_{y}, SiCO or other suitable compounds. STI 128 can be deposited using chemical vapor deposition (CVD), although other deposition methods can be employed. The STI 128 can then be etched, e.g., by RIE, to a top level of the substrate 106. In an embodiment, prior to forming the STI 128, a dielectric liner 126 can be conformally deposited in the shallow trenches. The dielectric liner 126 can include a nitride and be formed using, e.g., CVD.

The substrate 106 can be recessed to form trenches, e.g., by reactive ion etching (RIE). Within the trenches recessed into the substrate 106, a sacrificial placeholder 142 can be formed. The sacrificial placeholder 142 can be epitaxially grown in the trenches of the substrate 106. The sacrificial placeholder 142 can include SiGe or other epitaxial grown material that can be selectively removed relative to the substrate 106.

An epitaxial growth process is performed to form bottom source/drain (S/D) regions 148 and 150. The epitaxial growth process initiates growth from the semiconductor layers 112 (transistor channel). The channel width of the semiconductor layer 112 influences a width of S/D regions 148 and 150. The bottom S/D regions 148 and 150 are employed to form S/D regions for bottom transistors of the stacked FET device under construction. The bottom S/D regions 148 and 150 can include Si or SiGe and include faceted surfaces when epitaxial growth is not confined.

In an embodiment, the bottom S/D regions 148 and 150 can be designated as P-type or N-type devices. The P-type and N-type devices can have material selected for the bottom S/D regions 148 and 150. For example, if the bottom S/D regions 148 and 150 include N-type devices then the bottom S/D regions 148 and 150 can include Si. In another example, if the bottom S/D regions 148 and 150 include P-type devices then the bottom S/D regions 148 and 150 can include SiGe. The bottom S/D regions 148 and 150 can be appropriately doped during the formation of the bottom S/D regions 148 and 150 by epitaxial growth.

For example, the bottom S/D regions 148 and 150 can be doped by introducing p dopants (e.g., B, Ga, etc.) during epitaxial formation. Similarly, the bottom S/D regions 148 and 150 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

Bottom S/D region 148 and bottom S/D region 150 have different widths. These widths are determined by the semiconductor layers 112 from which epitaxial growth for the bottom S/D regions 148 and 150 is initiated. As illustratively shown, bottom S/D region 148 is narrower in width than bottom S/D region 150.

An epitaxial growth process is performed to form top S/D regions 152 and 154. The epitaxial growth process initiates growth from the semiconductor layers 112 (transistor channel). The top S/D regions 152 and 154 have a same width. The top S/D regions 152 and 154 are employed to form S/D regions for top transistors of the stacked FET device under construction. The top S/D regions 152 and 154 can include Si or SiGe and include faceted surfaces when epitaxial growth is not confined. In an embodiment, the top S/D regions 152 and 154 can be designated as P-type or N-type devices. The P-type and N-type devices can have material selected for the top S/D regions 152 and 154. For example, if the top S/D regions 152 and 154 include N-type devices then the top S/D regions 152 and 154 can include Si. In another example, if the top S/D regions 152 and 154 include P-type devices then the top S/D regions 152 and 154 can include SiGe. The top S/D regions 152 and 154 can be appropriately doped during the formation of the top S/D regions 152 and 154 by epitaxial growth.

For example, the top S/D regions 152 and 154 can be doped by introducing p dopants (e.g., B, Ga, etc.) during epitaxial formation. Similarly, the top S/D regions 152 and 154 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

The top S/D regions 152 and 154 have similar widths. These widths are determined by the semiconductor layers 112 from which epitaxial growth for the top S/D regions 152 and 154 is initiated. Gate structures for the transistors formed by the top S/D regions 152, 154 and the bottom S/D regions include replacement metal gates (RMG) (not shown).

An interlayer dielectric (ILD) 160 is formed on the wafer 100. The ILD 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 160 can be deposited using CVD, although other deposition methods can be employed.

The ILD 160 can be formed in stages including being disposed between the bottom S/D region 150 and the substrate 106 at position 163. A planarization process can be performed to planarize a top surface of the wafer 100. In one embodiment, the planarization process can include a chemical mechanical polish (CMP).

The wafer 100 includes two cells 110, 111 adjacent to one another and divided by dashed line 116 as depicted in FIG. 1. Cell 110 is associated with an I-shape while cell 111 is associated with an L-shape. In an embodiment each cell 110, 111 includes a two M1 width as indicated by a dashed line 114.

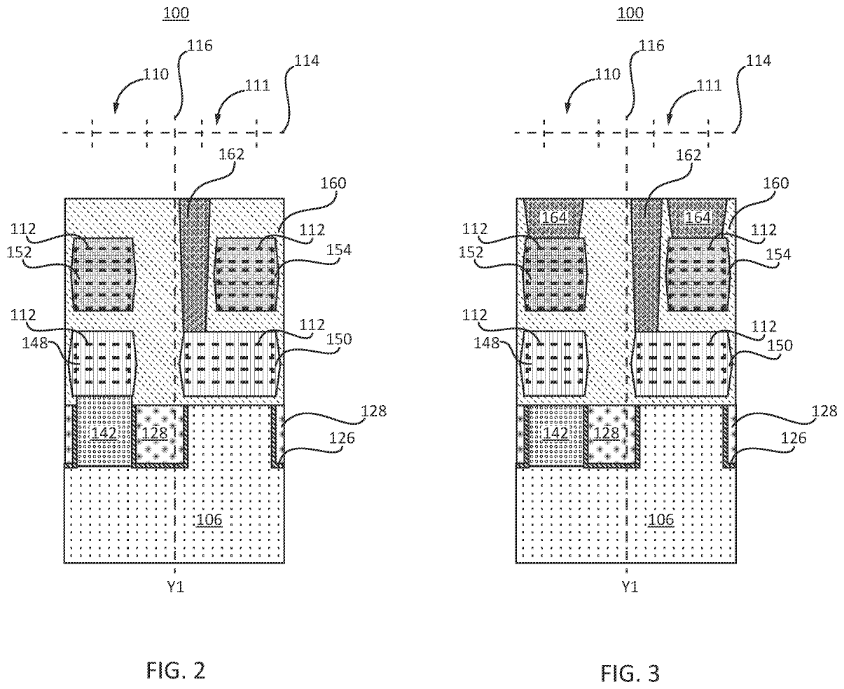

Referring to FIG. 2, a patterned photoresist (not shown) can be produced by applying a blanket photoresist layer to a surface of a hard mask material (not shown) and exposing the photoresist layer to a pattern of radiation, and then developing the pattern into the photoresist layer utilizing resist developer. The pattern in the photoresist layer is transferred to a hard mask by an etch process. The hard mask is then employed to etch contact holes into the ILD 160, e.g., by RIE. The hard mask is removed prior to a conductive fill to fill the contact holes.

An offset contact 162 (or via) is formed to make connections with the bottom S/D region 150 from a top side of the wafer 100. Trenches or holes are formed in the ILD 160 expose the underlying bottom S/D region 150. The bottom S/D region 150 having a greater width, provides a larger landing area for the offset contact 162, which also provide sufficient clearance from the top S/D region 154.

In useful embodiments, a silicide liner (not shown), such as Ti, Ni, NiPt is deposited first in the contact hole, then a diffusion barrier (not shown) can be formed in the contact hole prior to a conductive fill. The diffusion barrier can include, e.g., TiN, TaN, or similar materials.

A conductive fill is performed to fill the contact hole on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the offset contact 162.

Referring to FIG. 3, another patterned photoresist (not shown) can be produced by applying a blanket photoresist layer to a surface of a hard mask material (not shown) and exposing the photoresist layer to a pattern of radiation, and then developing the pattern into the photoresist layer utilizing resist developer. The pattern in the photoresist layer is transferred to a hard mask by an etch process. The hard mask is then employed to etch contact holes into the ILD 160, e.g., by RIE. The hard mask is removed prior to a conductive fill to fill the contact holes.

Middle of the line (MOL) contacts 164 are formed to make connections with the top S/D regions 152, 154 from a top side of the wafer 100. Trenches or holes are formed in the ILD 160 to expose the underlying top S/D regions 152, 154. The top S/D regions 152, 154 have a substantially similar width. The width of top S/D region 154 provides sufficient clearance for the offset contact 162 to pass.

In some embodiments, a silicide liner (not shown), such as Ti, Ni, NiPt is deposited first in the contact hole, then a diffusion barrier (not shown) can be formed in the contact hole prior to a conductive fill. The diffusion barrier can include, e.g., TiN, TaN, or similar materials.

A conductive fill is performed to fill the contact hole on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 164.

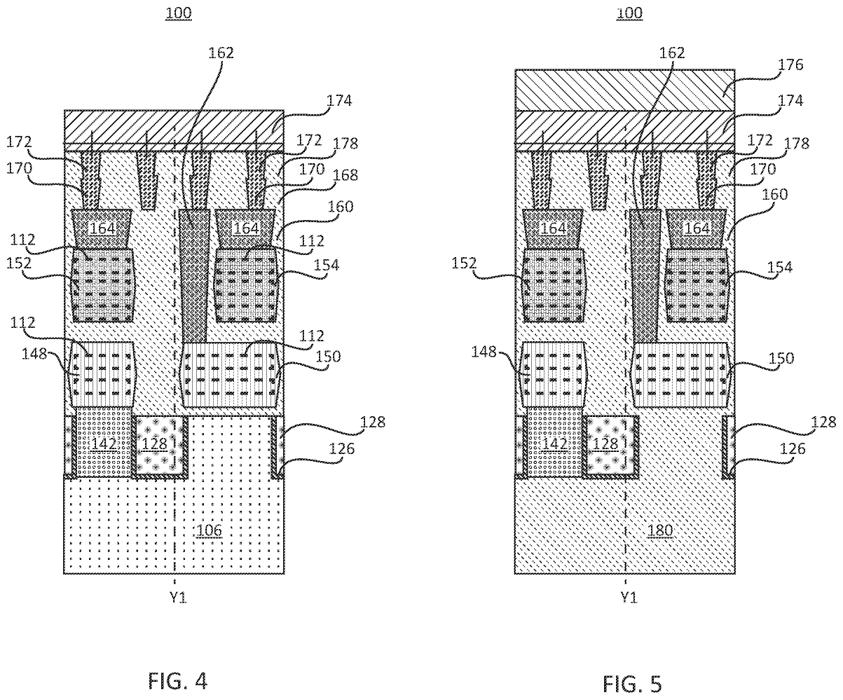

Referring to FIG. 4, a dielectric layer 168 extends the ILD 160 and is formed on the wafer 100. The dielectric layer 168 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 168 can be deposited using CVD, although other deposition methods can be employed. The dielectric layer 168 can be a same or different material from the ILD 160.

The dielectric layer 168 is patterned to form contact holes into the dielectric layer 168, e.g., by RIE to expose underlying structures, e.g., contacts 162 and 164. Vias 170 are formed to make connections with the contacts 162 and 164. In some embodiments, a diffusion barrier (not shown) can be formed in the contact hole prior to a conductive fill. The diffusion barrier can include, e.g., TiN, TaN, or similar materials.

A conductive fill is performed to fill the contact hole on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the vias 170.

The dielectric layer 168 is further extended by the deposition of another dielectric layer 178, which can include any suitable above-mentioned material. The dielectric layer 178 can be deposited using CVD, although other deposition methods can be employed. The dielectric layer 178 can be a same or different material from the ILD 160 or the dielectric layer 168.

The dielectric layer 178 is patterned to form trenches, e.g., by RIE to expose underlying structures, e.g., vias 170. Metal lines 172 (e.g., M1 metal lines) are formed to make connections with the vias 170. In some embodiments, a diffusion barrier (not shown) can be formed in the trenches prior to a conductive fill. The diffusion barrier can include, e.g., TiN, TaN, or similar materials.

A conductive fill is performed to fill the contact hole on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the metal lines 172.

Processing continues with the formation of a back end of the line (BEOL) layer 174, which can include metal structures and dielectric layers to complete the top side of the stacked FET device and provide electrical access to the devices formed.

Referring to FIG. 5, a carrier wafer 176 can be bonded to the BEOL layer 174. The carrier wafer 176 provides support and transportability to the wafer 100 for further processing which includes flipping the wafer 100 and removing portions of a bottom side of the stacked FET device. To continue processing, the wafer 100 can be flipped to process features on the bottom side of the stacked FET device. However, for clarity and consistency, the stacked FET device will be shown in the FIGS. in a same orientation as previously described with continued and consistent reference to bottom/top. The substrate 106 is removed from the bottom side of the stacked FET device. The substrate 106 can be removed by an etch process. A backside ILD 180 is formed in positions where the substrate 106 has been removed. The backside ILD 180 can be formed using the same processes and materials as ILD 160.

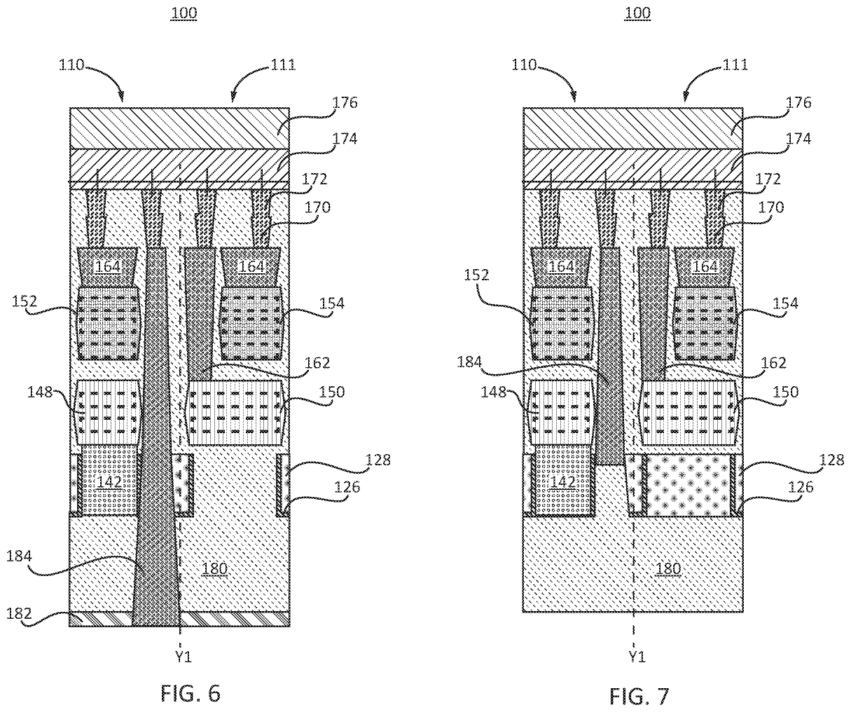

Referring to FIG. 6, a patternable material is deposited or spun onto a surface of the wafer 100, e.g., over the backside ILD 180. In an embodiment, an organic planarization layer (OPL) 182 is formed over a backside of the wafer 100. In some embodiments, an anti-reflective coating (ARC) layer (not shown) may be formed on the OPL 182 followed by a layer of photoresist (not shown) formed on the ARC layer. The layer of photoresist can be imaged with an image pattern and developed to form an etch mask. The OPL. 182 can be patterned in accordance with the etch mask to open up trenches in the OPL 182. Trenches are formed into the backside ILD 180 by an anisotropic etch. e.g., a RIE or IBE. The anisotropic etch, such as a plasma dry etch, is accurately controlled (using lithographic processing) to ensure proper placement for an extended backside via 184.

The extended backside via 184 is formed to make connections with the vias 170 from a backside of the wafer 100. In some embodiments, a diffusion barrier (not shown) can be formed in the trenches prior to a conductive fill. The diffusion barrier can include, e.g., TiN, TaN, or similar materials.

A conductive fill is performed to fill the trench on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the extended backside via 184.

The extended backside via 184 has a tapered geometry that remains within the cell 110 but is complementary to contact 164 in the cell 111 that neighbors cell 110. The extended backside via 184 and the offset contact 162 can be considered nested and efficiently use available space since one is a positive taper and the other is a negative taper.

Referring to FIG. 7, the extended backside via 184 is recessed by an etch process into the trench in which the extended backside via 184 is formed. The etch for recessing the extended backside via 184 is performed with the OPL 182 in place. A dielectric fill process using a dielectric material similar to the material employed for the backside ILD 180 fills in the void left by recessing of the extended backside via 184. The OPL 182 and excess dielectric are removed from the wafer 100 by a planarization process, e.g., CMP.

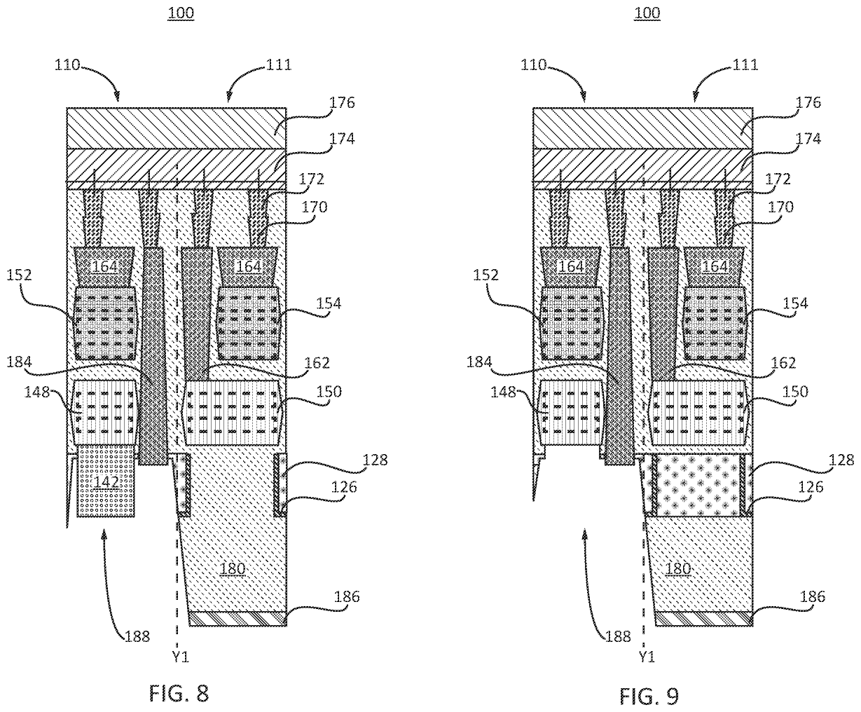

Referring to FIG. 8, another mask material is applied to the backside of the wafer 100 and patterned to provide an etch mask to remove portions of the backside ILD 180 in positions where backside contacts are to be formed. In an embodiment, the mask material can include OPL, although other hard mask materials can be employed. An etch process, e.g., RIE, is performed to expose the sacrificial placeholder 142 and the backside via 184 and form contact opening 188. The etch process stops before reaching the bottom S/D region 148.

Referring to FIG. 9, a selective etch removes the sacrificial placeholder 142 relative to the backside via 184, which remains intact. The selective etch process can include a dry etch or wet etch that selectively removes the sacrificial placeholder 142 relative to the bottom S/D region 148 and the backside via 184 within the contact opening 188. The corresponding bottom active region 148 is now exposed within the contact opening 188.

In some embodiments, a silicide liner (not shown), such as Ti, Ni, NiPt is deposited first in the contact opening 188, then a diffusion barrier (not shown) can be formed in the contact opening 188 prior to a conductive fill. The diffusion barrier can include, e.g., TiN, TaN, or similar materials.

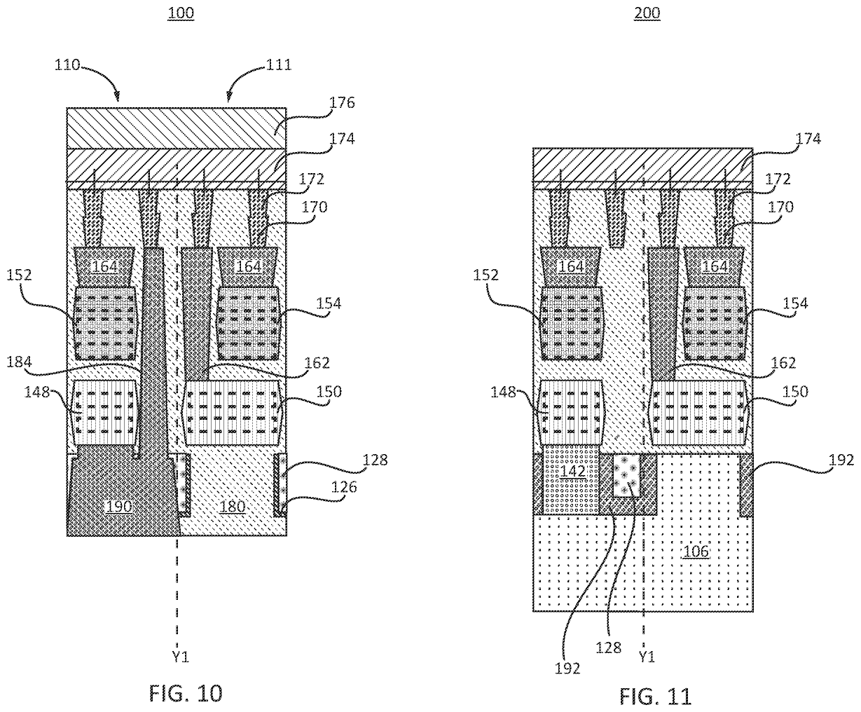

Referring to FIG. 10, a contact 190 is formed to make connections with the bottom S/D region 148 and a top of the backside via 184. A conductive fill is performed to fill the contact opening 188 on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the contact 190. The conductive fill may be recessed prior to the CMP to reduce the conductive fill on a surface of the wafer 100. Processing continues with the formation of backside interconnects and other structures.

With the complementary relationship between the extended backside via 184 and contact 164, a reliable structure is provided that reduces cell height for stacked FETs while keeping a same sheet width and relatively wide contact dimensions. The tapered geometry permits the cell 110 to complement the cell 111 that neighbors cell 110 to permit both cells 110, 111 to have a two M1 pitch cell height without sacrificing contact and via dimensions. The positive to negative taper (or vice versa) relationship between the extended backside via 184 and the contact 164, permit scaling (reducing) of cell height and prevent shorting between adjacent via chains or other conductive components.

In an example, a first cell can include an I-shape and an adjacent cell can include an L-shape to maintain sufficient dielectric material between via chains in the adjacent cells while permitting the two cells to fit within a two M1 pitch width. The I-shaped cell 110 includes epi-regions that are closer in size between a top epi region (the top S/D region 152) and a bottom epi region (the bottom S/D region 148). The L-shaped cell 111 is adjacent to the I-shaped cell 110 and includes epi-regions (the top S/D region 154) and the bottom S/D region 150) that are different in size. The bottom S/D region 150 is wider providing the L-shape and permitting an offset contact 162 to connect thereto as it passes the top S/D region 154. This makes for efficient use of available space and prevents shorting between the offset contact 162 and the extended backside via 184 while scaling the cell heights to within two M1 pitches. It should be understood that the cells 110 and 111 can be arranged adjacent to one another in a repeating pattern that can span across the wafer 100.

Referring to FIG. 11, in an alternate embodiment, a wafer 200 can be processed in a same way as wafer 100; however, a thicker liner 192 can be formed before forming STI 128. In an embodiment, prior to forming the STI 128, the thicker liner 192 can be conformally deposited in the shallow trenches. The thicker liner 192 can include a nitride and be formed using, e.g., CVD, although other materials and processes can be employed. The thicker liner 192 can include a thickness that is up to about five times thicker that the dielectric liner 126 (FIG. 10). The thicker liner 192 can be employed as a collar to ensure dielectric material exists at an interface between the backside via to be formed and the backside contact that connects to the backside via. The wafer 200 is shown after frontside interconnect formation (e.g., through BEOL layer 174).

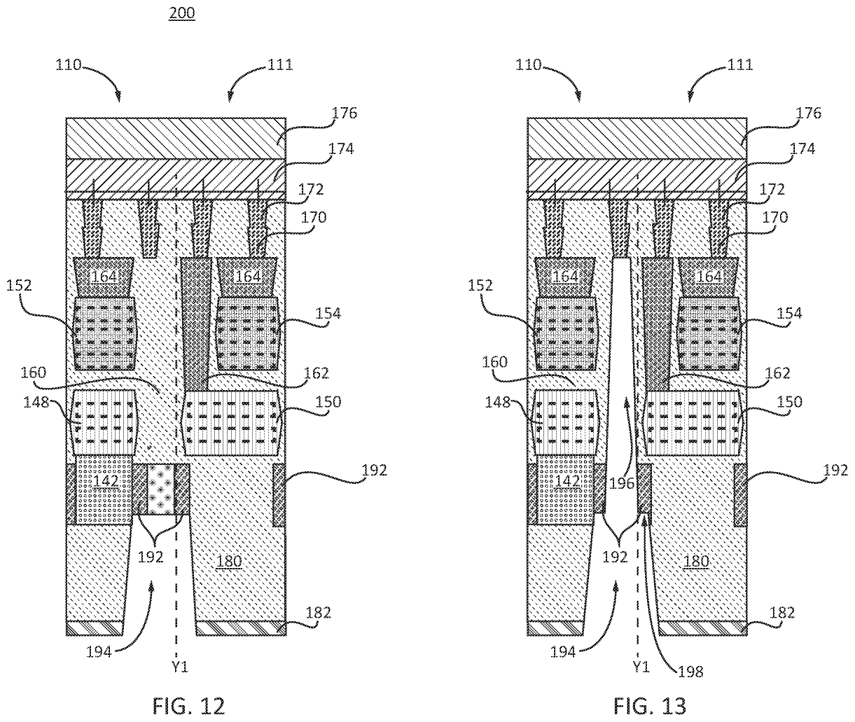

Referring to FIG. 12, the carrier wafer 176 can be bonded to the BEOL layer 174. To continue processing, the wafer 200 can be flipped to process features on the bottom side of the stacked FET device. However, for clarity and consistency, the stacked FET device will be shown in the FIGS. in a same orientation as previously described with continued and consistent reference to bottom/top. The substrate 106 is removed from the bottom side of the stacked FET device. The substrate 106 can be removed by an etch process. The backside ILD 180 is formed in positions where the substrate 106 has been removed. The backside ILD 180 can be formed using the same processes and materials as the ILD 160.

A patternable material is deposited or spun onto a surface of the wafer 200, e.g., over the backside ILD 180. In an embodiment, an OPL 182 is formed over a backside of the wafer 200. In some embodiments, an anti-reflective coating (ARC) layer (not shown) may be formed on the OPL 182 followed by a layer of photoresist (not shown) formed on the ARC layer. The layer of photoresist can be imaged with an image pattern and developed to form an etch mask. The OPL 182 can be patterned in accordance with the etch mask to open up trenches in the OPL 182. An opening 194 is etched into the backside ILD 180 by an anisotropic etch, e.g., a RIE or IBE. The anisotropic etch, such as a plasma dry etch, is accurately controlled (using lithographic processing) to remove a portion of the thicker liner 192 to expose the STI 128. A portion of the sacrificial placeholder 142 can also be exposed.

Referring to FIG. 13, the opening 194 is extended through the STI 128 forming a collar 198 through which an extended backside via (184, FIG. 9) will be formed. Once through the STI 128, etching continues into the ILD 160 to expose a via 170 on a frontside of the wafer 200. The etch process can include an anisotropic etch. e.g., a RIE or IBE. The anisotropic etch, such as a plasma dry etch provides a tapered geometry that remains within the cell 110 but is complementary to contact 164 in the cell 111 that neighbors cell 110. The collar 198 provides added manufacturing tolerance to the formation process of the extended backside via. The extended backside via (184) to be formed and the offset contact 162 can be considered nested and provide an efficient use of available space since one is a positive taper and the other is a negative taper.

Processing can continue with a conductive fill and CMP to form an extended backside via within the opening 194, and opening 196. In other embodiments, an extended backside via is formed and recessed. The sacrificial placeholder 142 is exposed and removed. A contact is formed that connects the extended backside via and the bottom S/D region 148, as shown in FIG. 10.

The extended backside via (not shown) is formed to make connections with the vias 170 from a backside of the wafer 200. In some embodiments, a diffusion barrier (not shown) can be formed in the trenches prior to a conductive fill. The diffusion barrier can include, e.g., TiN, TaN, or similar materials.

A conductive fill is performed to fill the opening 194 and opening 196 on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the extended backside via.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top.” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first cell adjacent to a second cell;
the first cell including first stacked source/drain regions on at least two levels;
the second cell including second stacked source/drain regions on the at least two levels;
the first cell including a first tapered vertical conductor; and
the second cell including a second tapered conductor having a taper opposite that of the first tapered vertical conductor to reduce cell heights of the first cell and the second cell.

2. The semiconductor device as recited in claim 1, wherein the first cell includes an I-shape having the first stacked source/drain regions on the at least two levels having a substantially same width.

3. The semiconductor device as recited in claim 2, wherein the first tapered vertical conductor includes an extended backside via that extends from a backside of the semiconductor device to a frontside of the semiconductor device.

4. The semiconductor device as recited in claim 2, further comprising a backside contact connected to one of the first stacked source/drain regions and the first tapered vertical conductor at a backside of the semiconductor device.

5. The semiconductor device as recited in claim 1, wherein the second cell includes an L-shape having the second stacked source/drain regions on the at least two levels having different widths.

6. The semiconductor device as recited in claim 5, wherein the second tapered conductor contacts a wider second stacked source/drain region.

7. The semiconductor device as recited in claim 1, wherein the first tapered vertical conductor passes through a shallow trench isolation (STI) region.

8. The semiconductor device as recited in claim 1, wherein the first tapered vertical conductor passes through a collar disposed about a shallow trench isolation (STI) region.

9. The semiconductor device as recited in claim 1, wherein the cell heights of the first cell and the second cell are each within two pitches of M1 metal lines.

10. A semiconductor device, comprising:
a first cell adjacent to a second cell;
the first cell including a first tapered vertical conductor that traverses two stacked source/drain regions in the first cell; and
the second cell including a second tapered vertical conductor that traverses a first stacked source/drain region in the second cell and connects to a second stacked source/drain region in the second cell, the second tapered vertical conductor being adjacent to the first tapered vertical conductor, the second tapered vertical conductor having a taper opposite that of the first tapered vertical conductor to reduce cell heights of the first cell and the second cell.

11. The semiconductor device as recited in claim 10, wherein the first cell includes an I-shape having the two stacked source/drain regions in the first cell with a substantially same width.

12. The semiconductor device as recited in claim 11, wherein the first tapered vertical conductor includes an extended backside via that extends from a backside of the semiconductor device to a frontside of the semiconductor device.

13. The semiconductor device as recited in claim 11, further comprising a backside contact connected to one of the two stacked source/drain regions in the first cell and the first tapered vertical conductor at a backside of the semiconductor device.

14. The semiconductor device as recited in claim 10, wherein the second cell includes an L-shape having the first stacked source/drain region in the second cell with a width that is narrower than the second stacked source/drain region in the second cell.

15. The semiconductor device as recited in claim 14, wherein the second tapered vertical conductor contacts the second stacked source/drain region.

16. The semiconductor device as recited in claim 10, wherein the first tapered vertical conductor passes through a shallow trench isolation (STI) region.

17. The semiconductor device as recited in claim 10, wherein the first tapered vertical conductor passes through a collar disposed about a shallow trench isolation (STI) region.

18. The semiconductor device as recited in claim 10, wherein the cell heights of the first cell and the second cell are each within two pitches of M1 metal lines.

19. A semiconductor device, comprising:
a first cell including first stacked source/drain regions having a substantially same width on at least two levels;
an extended backside via that extends from a backside of the semiconductor device to a frontside of the semiconductor device,
a second cell adjacent to the first cell including second stacked source/drain regions on the at least two levels having different widths;
a second tapered vertical conductor in the second cell having a taper opposite that of the extended backside via to reduce cell heights of the first cell and the second cell which are each within two pitches of M1 metal lines; and
a backside contact connected to one of the first stacked source/drain regions and the extended backside via at a backside of the semiconductor device.

20. The semiconductor device as recited in claim 19, wherein the extended backside via passes through a shallow trench isolation (STI) region.
